(19) United States
(12) Patent Application Publication
(10) Pub. No.: US 2015/0107991 A1
(43) Pub. Date: Apr. 23, 2015

(54) Fe-Pt-Based Sputtering Target Having Nonmagnetic Substance Dispersed Therein

(71) Applicant: JX Nippon Mining & Metals Corporation, Tokyo (JP)

(72) Inventor: Atsushi Sato, Ibaraki (JP)

(73) Assignee: JX Nippon Mining & Metals Corporation, Tokyo (JP)

(21) Appl. No.: 14/402,812

(22) PCT Filed: Aug. 21, 2013
(86) PCT No.: PCT/JP2013/072249

§ 371 Date: Nov. 21, 2014

(30) Foreign Application Priority Data
Oct. 25, 2012 (JP) 2012-235693

(51) Int. Cl. H01J 37/34; C23C 14/14

(52) U.S. Cl. CPC H01J 37/3429; C23C 14/14; H01J 2237/332
USPC 204/298.13

(57) ABSTRACT

A sintered compact sputtering target configured from an alloy having a composition comprising Pt at a molecular ratio of 35 to 55% and remainder being Fe, and a nonmagnetic substance dispersed in the alloy, wherein the nonmagnetic substance contains at least SiO₂, SiO₂ is amorphous, and a residual oxygen amount, which is obtained by subtracting an amount of oxygen contained as a constituent of the nonmagnetic substance from a total amount of oxygen contained in the target, is 0.07 wt % or less. An object of this invention is to provide a sintered compact sputtering target having a structure in which a nonmagnetic substance containing SiO₂ is dispersed in an Fe—Pt-based alloy and capable of suppressing the crystallization of SiO₂ into cristobalite, and reducing the amount of particles that is generated during sputtering.

The present invention relates to a sputtering target that is used for depositing a granular-type magnetic thin film in a magnetic recording medium, and particularly relates to a sintered compact sputtering target having a structure in which a nonmagnetic substance containing SiO₂ is dispersed in an Fe—Pt-based alloy.

In the field of magnetic recording as represented with hard disk drives, a material that is based on a ferromagnetic metal such as Co, Fe, or Ni is being used as the material of a magnetic thin film in a magnetic recording medium. For example, a Co—Cr-based or a Co—Cr—Pt-based ferromagnetic alloy having Co as its main component has been used for the magnetic thin film of a hard disk drive that adopts the in-plane magnetic recording system.

Moreover, a composite material made from a Co—Cr—Pt-based ferromagnetic alloy having Co as its main component and a nonmagnetic substance is often used for the magnetic thin film of a hard disk drive that adopts the perpendicular magnetic recording system which has been put into practical use in recent years. In addition, these magnetic thin films are often produced by sputtering a sputtering target made from the foregoing materials using a DC magnetron sputtering device in light of its high productivity.

Meanwhile, the recording density of hard disks is rapidly increasing year by year, and products having a capacity that exceeds 1 Tbit/in² is now being placed on the market. When the recording density reaches 1 Tbit/in², the size of the recording bit will fall below 10 nm and, in such a case, it is anticipated that the superparamagnetism caused by thermal fluctuation will become a problem, and it is further anticipated that the currently used materials of a magnetic recording medium; for instance, a material with higher magnetic crystalline anisotropy obtained by adding Pt to a Co—Cr-based alloy, will no longer be sufficient. This is because magnetic particles to stably behave as a ferromagnetic at a size of 10 nm or less need to possess even higher magnetic crystalline anisotropy.

Based on the reasons described above, an FePt phase having an L1₀ structure is attracting attention as a material for use in an ultrahigh density recording medium. Since an FePt phase having an L1₀ structure yields superior corrosion resistance and oxidation resistance in addition to having high magnetic crystalline anisotropy, it is expected to become a material that can be suitably applied as a magnetic recording medium.

Furthermore, in connection with using the FePt phase as a material for use in an ultrahigh density recording medium, demanded is the development of technology for dispersing the ordered FePt magnetic particles, in a magnetically isolated state, while densely aligning the orientation thereof as much as possible.

In light of the foregoing circumstances, a magnetic thin film having a granular structure in which the FePt magnetic particles having an L1₀ structure are encompassed with nonmagnetic substances such as oxides and carbon is being proposed for use in a magnetic recording medium of next-generation hard disks adopting the thermally assisted magnetic recording system. This magnetic thin film having a granular structure has a structure in which the magnetic particles are magnetically insulated through the interposition of nonmagnetic substances.

As patent documents relating to magnetic recording mediums having a magnetic thin film of a granular structure, there are, for example, Patent Document 1, Patent Document 2, Patent Document 3, Patent Document 4, Patent Document 5, and Patent Document 6 listed below.

As a magnetic thin film of a granular structure based on an FePt phase having the foregoing L1₀ structure, as one candidate, a magnetic thin film containing SiO₂ as a nonmagnetic substance at a volume ratio of 10 to 50% is attracting attention. In addition, the foregoing magnetic thin film of a granular structure is generally prepared by sputtering a target having a structure in which SiO₂ is dispersed in an Fe—Pt alloy. Moreover, the target used in the foregoing case is generally prepared via the powder sintering method.

Nevertheless, when sputtering a target in which SiO₂ is dispersed in an Fe—Pt alloy, there is a problem in that the microcracks that occur to the SiO₂ in the target cause the generation of particles. The term “particles” as used herein refers to the fine particular substance that is generated as dust from the target during sputtering. Since the particles that adhere onto the wafer deteriorate the production yield in the production process of thin films, there are demands for reducing the particles that are generated as dust from the target.

Patent Document 6 describes that the microcracks in the target in which SiO₂ is dispersed in an Fe—Pt alloy are caused by the SiO₂ in the target existing in the form of crystallized cristobalite. Thus, Patent Document 6 describes that, in order to suppress the transformation of SiO₂ into cristobalite, it is effective to use an amorphous SiO₂ powder as the raw material powder, and set the sintering temperature to 1120° C. or less. However, even when a sputtering target configured from a nonmagnetic substance containing SiO₂ and an Fe—Pt-based alloy is produced based on the conditions of Patent Document 6, there is a problem in that the crystallization of SiO₂ into cristobalite cannot be completely suppressed.

### PRIOR ART DOCUMENTS

### Patent Documents

Japanese Patent Application Publication No. 2000-306228

Japanese Patent Application Publication No. 2000-311329

Japanese Patent Application Publication No. 2008-59733

Japanese Patent Application Publication No. 2008-169464

Japanese Patent Application Publication No. 2004-152471

Japanese Patent No. 5032706

### SUMMARY OF THE INVENTION

### Problems to be Solved by the Invention

In light of the foregoing problems, an object of this invention is to provide a sintered compact sputtering target having a structure in which a nonmagnetic substance containing SiO₂ is dispersed in an Fe—Pt-based alloy and capable of suppressing the crystallization of SiO₂ into cristobalite, and reducing the amount of particles that is generated during sputtering.

### Means for Solving the Problems

In order to achieve the foregoing object, as a result of intense study, the present inventors and others discovered that the crystallization of SiO₂ into cristobalite can be suppressed and SiO₂ can be more finely dispersed in the parent metal by reducing the amount of excess oxygen in the target; that is, the amount of oxygen of components other than the constituent of the nonmagnetic substance containing SiO₂.

Based on the foregoing discovery, the present invention provides:

1) A sintered compact sputtering target configured from an alloy having a composition comprising Pt at a molecular ratio of 35 to 55% and remainder being Fe, and a nonmagnetic substance dispersed in the alloy, wherein the nonmagnetic substance contains at least SiO₂, SiO₂ is amorphous, and a residual oxygen amount, which is obtained by subtracting an amount of oxygen contained as a constituent of the nonmagnetic substance from a total amount of oxygen contained in the target, is 0.07 wt % or less.

2) The sputtering target according to 1) above, wherein the sputtering target includes, as an additive element to be added to the alloy, one or more types of elements selected from Ag, Au, B, Co, Cr, Cu, Ga, Ge, Mn, Mo, Nb, Ni, Pd, Re, Rh, Ru, Sn, Ta, W, V, and Zn at a molecular ratio of 0.5 to 15%.

3) The sputtering target according to 1) or 2) above, wherein the sputtering target includes, as a nonmagnetic substance other than SiO₂, one or more types selected from C (carbon), or a carbide of an element selected from B, Ca, Nb, Si, Ta, Ti, W, and Zr, or a nitride of an element selected from Al, B, Ca, Nb, Si, Ta, Ti, and Zr, or an oxide of an element selected from Al, B, Ba, Be, Ca, Ce, Cr, Dy, Er, Eu, Ga, Gd, Ho, Li, Mg, Mn, Nb, Nd, Pr, Sc, Sm, Sr, Ta, Tb, Ti, V, Y, Zn, and Zr.

4) The sputtering target according to any one of 1) to 3) above, wherein a volume ratio of the nonmagnetic substance in the target is 10 to 55%.

### Effect of the Invention

The Fe—Pt-based sputtering target having a nonmagnetic substance dispersed therein according to the present invention can considerably reduce the generation of particles during sputtering even though SiO₂ is contained as a nonmagnetic substance. In other words, it is possible to improve the production yield during deposition.

### BRIEF DESCRIPTION OF THE DRAWINGS

FIG. 1 is an image of the structure upon observing the polished surface of the sputtering target of Example 1 with an optical microscope.

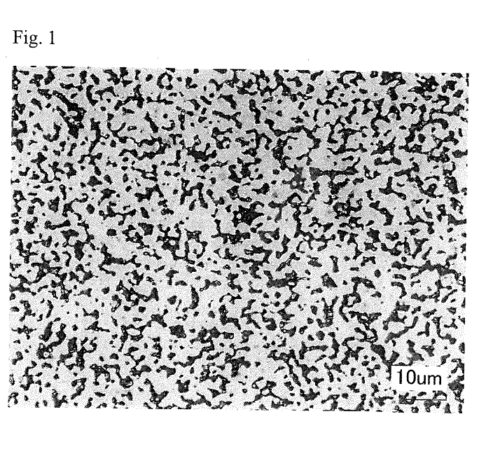

### DETAILED DESCRIPTION

The Fe—Pt-based sputtering target having a nonmagnetic substance dispersed therein according to the present invention is a sintered compact sputtering target configured from an alloy having a composition comprising Pt at a molecular ratio of 35 to 55% and remainder being Fe, and a nonmagnetic substance dispersed in the alloy, wherein the nonmagnetic substance contains at least SiO₂, SiO₂ is amorphous, and a residual oxygen amount, which is obtained by subtracting an amount of oxygen contained as a constituent of the nonmagnetic substance from a total amount of oxygen contained in the target, is 0.07 wt % or less. This is the basis of the present invention.

The content of Pt in the Fe—Pt alloy composition is preferably contained at a molecular ratio of 35% or more and 55% or less. When the content of Pt in the Fe—Pt alloy is contained at a molecular ratio of less than 35%, there are cases where the FePt phase of the L1₀ structure cannot be obtained, and when the content of Pt in the Fe—Pt alloy is contained at a molecular ratio exceeding 55%, similarly, there are cases where the FePt phase of the L1₀ structure cannot be obtained. Moreover, a magnetic film of a favorable granular structure can be obtained as a result of SiO₂ being contained as a nonmagnetic substance.

Moreover, with the target of the present invention, the SiO₂ contained in the target is amorphous. Accordingly, a target in which the SiO₂ exists in the form of cristobalite is outside the scope of the present invention. The crystalline state of the SiO₂ can be checked from the diffraction profile that is obtained by measuring the polished surface of a small piece of the target using an X-ray diffraction device. Generally speaking, when the SiO₂ is amorphous, no clear diffraction peak deriving from the SiO₂ will appear.

Whether the SiO₂ is amorphous can specifically be determined by analyzing the X-ray diffraction profile as follows.

Foremost, an average value of the signal strength in the background region of the diffraction profile is obtained, and this is used as the baseline. Next, an absolute value of the deviation between the signal strength and the baseline is integrated in the background region to obtain the integrated intensity of the background. Subsequently, the integrated intensity of the diffraction peak deriving from the SiO₂ crystals is obtained. The integrated intensity of the diffraction peak is obtained by integrating the deviation from the base line obtained in the background region before and after the diffraction peak. Subsequently, when the value obtained by dividing the integrated intensity of the diffraction peak by the integrated intensity of the background is 3 or more, it can be determined that there is a diffraction peak deriving from the crystallized SiO₂, and that the SiO₂ is not amorphous.

Note that, as the baseline, a linear function obtained with the least-squares method with regard to the signal strength of the background region may also be used in substitute for the average value of the signal strength, and this method is of higher precision. Moreover, upon dividing the integrated intensity by the integrated intensity, the integrated intensity per unit diffraction angle obtained by dividing the integrated value by the diffraction angle width of the domain of integration is used rather than using the integrated value itself.

Furthermore, with the target of the present invention, an important factor is that the residual oxygen amount, which is obtained by subtracting the amount of oxygen contained as a constituent of the nonmagnetic substance from the total amount of oxygen contained in the target, is 0.07 wt % or less. This is because, when this value exceeds 0.07 wt %, crystallization of SiO₂ into cristobalite is promoted during sintering due to the influence of the trace amounts of iron oxide that is generated in the Fe—Pt-based alloy. The residual oxygen amount is desirably 0.05 wt % or less.

The amount of oxygen contained in the target can be obtained by measuring a small piece of the target using an oxygen analyzer that adopts the inert gas fusion-infrared absorption technique. And, while it is difficult to selectively and directly measure the oxygen amount of the constituent of the nonmagnetic substance, the oxygen amount of the nonmagnetic substance can be obtained using the stoichiometric ratio of the nonmagnetic substance from the content of the nonmagnetic substance in the target measured using ICP-AES or other devices. In addition, the residual oxygen amount of the target can be indirectly obtained by subtracting the oxygen amount of the nonmagnetic substance calculated using the stoichiometric ratio from the oxygen amount of the target measured with the oxygen analyzer.

Moreover, the sputtering target of the present invention may also include, as an additive element to be added to the Fe—Pt alloy, one or more types of elements selected from Ag, Au, B, Co, Cr, Cu, Ga, Ge, Mn, Mo, Nb, Ni, Pd, Re, Rh, Ru, Sn, Ta, W, V, and Zn at a molecular ratio of 0.5 to 15%. These elements are added mainly for lowering the temperature of the heat treatment that is performed for developing the L1₀ structure. When the additive element is added in an additive amount at a molecular ratio that is less than 0.5% molecular ratio, it is difficult to obtain the intended effect. Meanwhile, when the additive element is added in an additive amount at a molecular ratio that exceeds 15%, there are cases where the characteristics of the magnetic thin film are impaired.

Moreover, the sputtering target of the present invention may also include, as a nonmagnetic substance other than SiO₂, one or more types selected from C (carbon), or a carbide of an element selected from B, Ca, Nb, Si, Ta, Ti, W, and Zr, or a nitride of an element selected from Al, B, Ca, Nb, Si, Ta, Ti, and Zr, or an oxide of an element selected from Al, B, Ba, Be, Ca, Ce, Cr, Dy, Er, Eu, Ga, Gd, Ho, Li, Mg, Mn, Nb, Nd, Pr, Sc, Sm, Sr, Ta, Tb, Ti, V, Y, Zn, and Zr. Since these nonmagnetic substances take on a structure which insulates the magnetic interaction of the magnetic particles, together with the SiO₂, in the magnetic thin film prepared by sputtering the sputtering target of the present invention, the prepared magnetic thin film can obtain favorable magnetic properties.

Moreover, with the sputtering target of the present invention, it is particularly effective when the volume ratio of the nonmagnetic substance in the target is 10 to 55%. This is because the foregoing range is an appropriate volume ratio for realizing a favorable granular structure in the magnetic thin film prepared by sputtering the sputtering target of the present invention. Note that the volume ratio of the nonmagnetic substance can be obtained from the content of the nonmagnetic substance calculated from the analytical value of the components of the target. Otherwise, the volume ratio of the nonmagnetic substance can also be obtained from the area ratio of the nonmagnetic substance on the polished surface of a small piece that is cut out from the target. In the foregoing case, the area ratio is desirably 10 to 55%.

The sputtering target of the present invention is prepared via the powder sintering method. The respective raw material powders are prepared upon preparing the sputtering target of the present invention. These powders desirably have a grain size of 0.5 μm or more and 10 μm or less. When the grain size of the raw material powders is too small, problems will arise in that the oxygen in the raw material powder becomes too great or the raw material powders become aggregated and, therefore, powders having a grain size of 0.5 μm or more are used. Meanwhile, when the grain size of the raw material powder is too large, it becomes difficult to finely disperse the nonmagnetic substance in the alloy and, therefore, powders having a grain size of 10 μm or less are used.

Moreover, an amorphous SiO₂ powder is used as the SiO₂ powder, and it is effective to use a raw material that is amorphous to begin with. In addition, as the metal powders, alloy powders of the Fe—Pt powder and the like may be used in substitute for the powders of the respective metal elements. In particular, while this also depends on the composition, an alloy powder containing Pt is effective for reducing the oxygen amount in the raw material powder. When using an alloy powder, the grain size of such alloy powder is preferably 0.5 μm or more and 10 μm or less.

Subsequently, the foregoing powders are weighed to achieve the intended composition, and pulverized and mixed using a known means such as a ball mill. Here, desirably, inert gas is sealed in the pulverizing vessel in order to suppress the oxidation of the raw material powders. Thereafter, the pulverized raw material powders are subject to reduction heat treatment in a reducing atmosphere at a temperature range of 700 to 900° C. in order to eliminate the oxygen in the raw material powder. When the heat treatment temperature is less than 700° C., oxygen cannot be sufficiently eliminated, and when the heat treatment temperature exceeds 900° C., this is undesirable since the sintering of the raw material powder will advance and it will become difficult to maintain the powder condition.

The thus obtained mixed powder is molded and sintered in a vacuum atmosphere or an inert gas atmosphere via the hot press method. In addition to the hot press method, various pressure sintering methods such as the plasma discharge sintering method may be used. In particular, the hot isostatic press sintering method is effective for improving the density of the sintered compact. The holding temperature during sintering is set to be within a temperature range that is lower than 1100° C. for suppressing the crystallization of SiO₂.

Moreover, the molding and sintering processes are not limited to the hot press method, and the plasma discharge sintering method or the hot isostatic press sintering method may also be used. The holding temperature during sintering is preferably set to a temperature that is lowest within the temperature range capable of sufficiently densifying the target. While this will also depend on the composition of the target, in many cases the holding temperature is set to be within the temperature range of 900 to 1100° C.

The thus obtained sintered compact is processed into an intended shape using a lathe in order to prepare the sputtering target of the present invention.

Based on the process described above, it is possible to prepare a sintered compact sputtering target having a structure in which a nonmagnetic substance containing SiO₂ is dispersed in the Fe—Pt-based alloy. The thus produced sputtering target of the present invention is effective as a sputtering target for use in the deposition of a magnetic thin film having a granular structure.

### EXAMPLES

The present invention is now explained based on the following Examples and Comparative Examples. Note that these Examples are merely illustrative, and the present invention is not limited in any way by these Examples. In other words, the present invention is limited only based on its scope of claims, and the present invention covers various modifications other than the Examples included herein.

### Example 1

As raw material powders, an Fe powder having an average grain size of 3 μm, a Pt powder having an average grain size of 3 μm, and an amorphous SiO₂ powder having an average grain size of 1 μm were prepared.

These powders were weighed at the following molecular ratio to obtain a total weight of 2050 g so that the volume ratio of SiO₂ would be approximately 39%.

Molecular ratio: 84(50Fe-50Pt)-16SiO₂

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.1, and it was determined that the SiO₂ is not crystallized. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 4.37 wt %, and the Si content was 3.80 wt %. When the SiO₂ content in the target was calculated with the atomic weight of Si as 28.0855 and the atomic weight of O as 15.9994, the result was 8.13 wt %. Accordingly, the content of O as the constituent of the SiO₂ was estimated as being 4.33 wt %. Subsequently, the residual oxygen amount of the target was obtained from the foregoing measurement results, and the result was 0.04 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 24 particles.

### Comparative Example 1

As raw material powders, an Fe powder having an average grain size of 3 μm, a Pt powder having an average grain size of 3 μm, and an amorphous SiO₂ powder having an average grain size of 1 μm were prepared.

These powders were weighed at the following molecular ratio to obtain a total weight of 2050 g so that the volume ratio of SiO₂ would be approximately 39%.

Molecular ratio: 84(50Fe-50Pt)-16SiO₂

Subsequently, the weighed powders were placed in a ball mill pot having a capacity of 10 liters together with Zirconia balls as the grinding medium, and rotated and mixed for 4 hours. Here, unlike Example 1, Ar gas was not sealed in the mixing vessel, and mixing was performed in the atmosphere. The mixed powder removed from the ball mill was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 1. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 8.7. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 4.50 wt %, and the Si content was 3.84 wt %. When the SiO₂ content in the target was calculated with the atomic weight of Si as 28.0855 and the atomic weight of O as 15.9994, the result was 8.22 wt %. Accordingly, the content of O as the constituent of the SiO₂ was estimated as being 4.38 wt %. Subsequently, the residual oxygen amount of the target was obtained from the foregoing measurement results, and the result was 0.12 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 623 particles. The number of particles was extremely great in comparison to Example 1.

### Comparative Example 2

As raw material powders, an Fe powder having an average grain size of 3 μm, a Pt powder having an average grain size of 3 μm, and an amorphous SiO₂ powder having an average grain size of 1 μm were prepared.

These powders were weighed at the following molecular ratio to obtain a total weight of 2050 g so that the volume ratio of SiO₂ would be approximately 39%.

Molecular ratio: 84(50Fe-50Pt)-16SiO₂

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

Unlike Example 1, the hot press conditions were as follows; a vacuum atmosphere, rate of temperature increase of 300° C./hour, holding temperature of 1150° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 1. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 6.3. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 4.44 wt %, and the Si content was 3.84 wt %. When the SiO₂ content in the target was calculated with the atomic weight of Si as 28.0855 and the atomic weight of O as 15.9994, the result was 8.22 wt %. Accordingly, the content of O as the constituent of the SiO₂ was estimated as being 4.38 wt %. Subsequently, the residual oxygen amount of the target was obtained from the foregoing measurement results, and the result was 0.06 wt %. The reason why SiO₂ crystallized into cristobalite even though the residual oxygen amount was low is considered to be because crystallization was promoted due to the high sintering temperature.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 517 particles. The number of particles was extremely great in comparison to Example 1.

### Example 2

As raw material powders, an Fe powder having an average grain size of 3 μm, a Pt powder having an average grain size of 3 μm, a Cu powder having an average grain size of 5 μm, and an amorphous SiO₂ powder having an average grain size of 1 μm were prepared.

These powders were weighed at the following molecular ratio to obtain a total weight of 1800 g so that the volume ratio of SiO₂ would be approximately 46%.

Molecular ratio: 80(45Fe-45Pt-10Cu)-20SiO₂

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

The hot press conditions were as follows; namely, a vacuum atmosphere, rate of temperature increase of 300° C./hour, holding temperature of 1000° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.1. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 6.00 wt %, and the Si content was 5.22 wt %. When the SiO₂ content in the target was calculated with the atomic weight of Si as 28.0855 and the atomic weight of O as 15.9994, the result was 11.17 wt %. Accordingly, the content of O as the constituent of the SiO₂ was estimated as being 5.95 wt %. Subsequently, the residual oxygen amount of the target was obtained from the foregoing measurement results, and the result was 0.05 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 17 particles.

### Comparative Example 3

As raw material powders, an Fe powder having an average grain size of 3 μm, a Pt powder having an average grain size of 3 μm, a Cu powder having an average grain size of 5 μm, and an amorphous SiO₂ powder having an average grain size of 1 μm were prepared.

These powders were weighed at the following molecular ratio to obtain a total weight of 1800 g so that the volume ratio of SiO₂ would be approximately 46%.

Molecular ratio: 80(45Fe-45Pt-10Cu)-20SiO₂

The weighed powders were sealed in a ball mill pot having a capacity of 10 liters together with Zirconia balls as the grinding medium, and rotated and mixed for 4 hours. Here, unlike Example 2, Ar gas was not sealed in the mixing vessel, and mixing was performed in the atmosphere. The mixed powder removed from the ball mill was subsequently filled in a carbon mold and hot pressed.

The hot press conditions were as follows; namely, a vacuum atmosphere, rate of temperature increase of 300° C./hour, holding temperature of 1000° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 2. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 11.5. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 6.10 wt %, and the Si content was 5.19 wt %. When the SiO₂ content in the target was calculated with the atomic weight of Si as 28.0855 and the atomic weight of O as 15.9994, the result was 11.10 wt %. Accordingly, the content of O as the constituent of the SiO₂ was estimated as being 5.91 wt %. Subsequently, the residual oxygen amount of the target was obtained from the foregoing measurement results, and the result was 0.10 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 385 particles. The number of particles was great in comparison to Example 2.

### Comparative Example 4

As raw material powders, an Fe powder having an average grain size of 3 μm, a Pt powder having an average grain size of 3 μm, a Cu powder having an average grain size of 5 μm, and an amorphous SiO₂ powder having an average grain size of 1 μm were prepared.

These powders were weighed at the following molecular ratio to obtain a total weight of 1800 g so that the volume ratio of SiO₂ would be approximately 46%.

Molecular ratio: 80(45Fe-45Pt-10Cu)-20SiO₂

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

Unlike Example 1, the hot press conditions were as follows; a vacuum atmosphere, rate of temperature increase of 300° C./hour, holding temperature of 1100° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 2. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 8.8. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The residual oxygen amount of the target was subsequently obtained from the foregoing measurement results. The measurement results were as follows; the oxygen amount in the target was 6.04 wt %, and the Si content was 5.26 wt %. When the SiO₂ content in the target was calculated with the atomic weight of Si as 28.0855 and the atomic weight of O as 15.9994, the result was 11.25 wt %. Accordingly, the content of O as the constituent of the SiO₂ was estimated as being 5.99 wt %. The result was 0.05 wt %. The reason why SiO₂ crystallized into cristobalite even though the residual oxygen amount was low is considered to be because crystallization was promoted due to the high sintering temperature.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 553 particles. The number of particles was extremely great in comparison to Example 2.

### Example 3

As raw material powders, an Fe powder having an average grain size of 3 μm, a Pt powder having an average grain size of 3 μm, a C powder having an average grain size of 10 μm, and an amorphous SiO₂ powder having an average grain size of 1 μm were prepared.

These powders were weighed at the following molecular ratio to obtain a total weight of 2200 g so that the total volume ratio of C and SiO₂ would be approximately 33%.

Molecular ratio: 80(50Fe-50Pt)-10SiO₂-10C

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.0. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 3.05 wt %, and the Si content was 2.65 wt %. When the SiO₂ content in the target was calculated with the atomic weight of Si as 28.0855 and the atomic weight of O as 15.9994, the result was 5.67 wt %. Accordingly, the content of O as the constituent of the SiO₂ was estimated as being 3.02 wt %. Subsequently, the residual oxygen amount of the target was obtained from the foregoing measurement results, and the result was 0.03 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 57 particles.

### Example 4

As raw material powders, an Fe powder having an average grain size of 3 μm, a Pt powder having an average grain size of 3 μm, an amorphous SiO₂ powder having an average grain size of 1 μm, and a BN powder having an average grain size of 10 μm were prepared.

These powders were weighed at the following molecular ratio to obtain a total weight of 2100 g so that the volume ratio of SiO₂ would be approximately 22%.

Molecular ratio: 82(50Fe-50Pt)-8SiO₂-10BN

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.0. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 2.48 wt %, and the Si content was 2.13 wt %. When the SiO₂ content in the target was calculated with the atomic weight of Si as 28.0855 and the atomic weight of O as 15.9994, the result was 4.56 wt %. Accordingly, the content of O as the constituent of the SiO₂ was estimated as being 2.43 wt %. Subsequently, the residual oxygen amount of the target was obtained from the foregoing measurement results, and the result was 0.05 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 35 particles.

### Comparative Example 5

As raw material powders, an Fe powder having an average grain size of 3 μm, a Pt powder having an average grain size of 3 μm, an amorphous SiO₂ powder having an average grain size of 1 μm, and a BN powder having an average grain size of 10 μm were prepared.

These powders were weighed at the following molecular ratio to obtain a total weight of 2100 g so that the volume ratio of SiO₂ would be approximately 22%.

Molecular ratio: 82(50Fe-50Pt)-8SiO₂-10BN

The weighed powders were sealed in a ball mill pot having a capacity of 10 liters together with Zirconia balls as the grinding medium, and rotated and mixed for 4 hours. Here, unlike Example 2, Ar gas was not sealed in the mixing vessel, and mixing was performed in the atmosphere. The mixed powder removed from the ball mill was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 2. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 8.6. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 2.73 wt %, and the Si content was 2.16 wt %. When the SiO₂ content in the target was calculated with the atomic weight of Si as 28.0855 and the atomic weight of O as 15.9994, the result was 4.62 wt %. Accordingly, the content of O as the constituent of the SiO₂ was estimated as being 2.46 wt %. Subsequently, the residual oxygen amount of the target was obtained from the foregoing measurement results, and the result was 0.27 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 263 particles. The number of particles was great in comparison to Example 4.

### Comparative Example 6

As raw material powders, an Fe powder having an average grain size of 3 μm, a Pt powder having an average grain size of 3 μm, an amorphous SiO₂ powder having an average grain size of 1 μm, and a BN powder having an average grain size of 10 μm were prepared.

These powders were weighed at the following molecular ratio to obtain a total weight of 2100 g so that the volume ratio of SiO₂ would be approximately 22%.

Molecular ratio: 82(50Fe-50Pt)-8SiO₂-10BN

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

Unlike Example 4, the hot press conditions were as follows; a vacuum atmosphere, rate of temperature increase of 300° C./hour, holding temperature of 1200° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 2. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 12.5. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The residual oxygen amount of the target was subsequently obtained from the foregoing measurement results. The measurement results were as follows; the oxygen amount in the target was 2.43 wt %, and the Si content was 2.10 wt %. When the SiO₂ content in the target was calculated with the atomic weight of Si as 28.0855 and the atomic weight of O as 15.9994, the result was 4.49 wt %. Accordingly, the content of O as the constituent of the SiO₂ was estimated as being 2.39 wt %. The result was 0.04 wt %. The reason why SiO₂ crystallized into cristobalite even though the residual oxygen amount was low is considered to be because crystallization was promoted due to the high sintering temperature.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 744 particles. The number of particles was extremely great in comparison to Example 4.

### Example 5

As raw material powders, an Fe powder having an average grain size of 3 μm, a Pt powder having an average grain size of 3 μm, an amorphous SiO₂ powder having an average grain size of 1 μm, and a NbC powder having an average grain size of 5 μm were prepared.

These powders were weighed at the following molecular ratio to obtain a total weight of 2400 g so that the volume ratio of SiO₂ would be approximately 22%.

Molecular ratio: 86(55Fe-45Pt)-8SiO₂-6NbC

Subsequently, among the weighed powders, the Fe powder, the Pt powder and the SiO₂ powder were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. The thus obtained powder and the NbC powder were sealed using Ar gas in a ball mill pot having a capacity of 10 liters together with Zirconia balls as the grinding medium, and rotated and mixed for 1 hour. The obtained powder was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.1. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 3.11 wt %, and the Si content was 2.70 wt %. When the SiO₂ content in the target was calculated with the atomic weight of Si as 28.0855 and the atomic weight of O as 15.9994, the result was 5.78 wt %. Accordingly, the content of O as the constituent of the SiO₂ was estimated as being 3.08 wt %. Subsequently, the residual oxygen amount of the target was obtained from the foregoing measurement results, and the result was 0.03 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 120 particles.

### Comparative Example 7

As raw material powders, an Fe powder having an average grain size of 3 μm, a Pt powder having an average grain size of 3 μm, an amorphous SiO₂ powder having an average grain size of 1 μm, and a NbC powder having an average grain size of 5 μm were prepared.

These powders were weighed at the following molecular ratio to obtain a total weight of 2400 g so that the volume ratio of SiO₂ would be approximately 22%.

Molecular ratio: 86(55Fe-45Pt)-8SiO₂-6NbC

The weighed powders were sealed in a ball mill pot having a capacity of 10 liters together with Zirconia balls as the grinding medium, and rotated and mixed for 4 hours. Here, unlike Example 5, Ar gas was not sealed in the mixing vessel, and mixing was performed in the atmosphere. The mixed powder removed from the ball mill was subsequently filled in a carbon mold and hot pressed.

The hot press conditions were as follows; namely, a vacuum atmosphere, rate of temperature increase of 300° C./hour, holding temperature of 1050° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured under the same conditions as Example 2. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 6.8. Based on the foregoing results, a diffraction peak of 2θ=21.98° deriving from cristobalite, which was crystallized SiO₂, was observed.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 3.23 wt %, and the Si content was 2.73 wt %. When the SiO₂ content in the target was calculated with the atomic weight of Si as 28.0855 and the atomic weight of O as 15.9994, the result was 5.84 wt %. Accordingly, the content of O as the constituent of the SiO₂ was estimated as being 3.11 wt %. Subsequently, the residual oxygen amount of the target was obtained from the foregoing measurement results, and the result was 0.12 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 567 particles. The number of particles was great in comparison to Example 5.

### Example 6

As raw material powders, an Fe powder having an average grain size of 3 μm, a Pt powder having an average grain size of 3 μm, an amorphous SiO₂ powder having an average grain size of 1 μm, and a B₂O₃ powder having an average grain size of 5 μm were prepared.

These powders were weighed at the following molecular ratio to obtain a total weight of 2200 g so that the volume ratio of SiO₂ would be approximately 20%.

Molecular ratio: 88(50Fe-50Pt)-8SiO₂-4B₂O₃

Subsequently, among the weighed powders, the Fe powder, the Pt powder and the SiO₂ powder were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. The thus obtained powder and the B₂O₃ powder were sealed using Ar gas in a ball mill pot having a capacity of 10 liters together with Zirconia balls as the grinding medium, and rotated and mixed for 1 hour. The obtained powder was subsequently filled in a carbon mold and hot pressed.

The hot press conditions were as follows; namely, a vacuum atmosphere, rate of temperature increase of 300° C./hour, holding temperature of 950° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.3. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 3.68 wt %, the Si content was 1.90 wt %, and the B content was 0.68 wt %. When the SiO₂ content in the target was calculated with the atomic weight of Si as 28.0855, the atomic weight of B as 10.81 and the atomic weight of O as 15.9994, the result was 4.06 wt %, and the B₂O₃ content in the target based on the same calculation was 2.19 wt %. Accordingly, the content of 0 as the constituent of the SiO₂ was estimated as being 2.16 wt %, and the content of 0 as the constituent of the B₂O₃ was estimated as being 1.51 wt %. Subsequently, the residual oxygen amount of the target was obtained from the foregoing measurement results, and the result was 0.01 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 23 particles.

### Example 7

As raw material powders, an Fe powder having an average grain size of 3 μm, a Pt powder having an average grain size of 3 μm, an amorphous SiO₂ powder having an average grain size of 1 μm, and a Ag powder having an average grain size of 2 μm were prepared.

These powders were weighed at the following molecular ratio to obtain a total weight of 2100 g so that the volume ratio of SiO₂ would be approximately 38%.

Molecular ratio: 84(45Fe-45Pt-10Ag)-16SiO₂

The weighed powders were sealed using Ar gas in a ball mill pot having a capacity of 10 liters together with Zirconia balls as the grinding medium, and rotated and mixed for 4 hours. The mixed powder removed from the ball mill was subject to reduction heat treatment under the following conditions; namely, a hydrogen atmosphere, rate of temperature increase of 300° C./hour, holding temperature of 800° C., and holding time of 2 hours. After the reduction heat treatment, the mixed powder was cooled naturally until reaching room temperature, and the mixed powder was subsequently filled in a carbon mold and hot pressed.

The hot press conditions were as follows; namely, a vacuum atmosphere, rate of temperature increase of 300° C./hour, holding temperature of 950° C., holding time of 2 hours, and pressure of 30 MPa was applied from the starting time of a temperature increase to the end of the holding time. After the end of holding, the sintered compact was left in the chamber and cooled naturally.

Subsequently, the sintered compact was removed from the carbon mold and subject to hot isostatic pressing. The hot isostatic pressing conditions were as follows; namely, rate of temperature increase of 300° C./hour, holding temperature of 950° C., holding time of 2 hours, gas pressure of Ar gas was gradually increased from the starting time of a temperature increase, and pressure of 150 MPa was applied during holding at 950° C. After the end of holding, the sintered compact was left in the furnace and cooled naturally.

Then, a part of the sintered compact was cut out, the cross section thereof was polished, and a sample for X-ray diffraction measurement was thereby prepared. The X-ray diffraction profile of this sample was measured based on the θ/2θ method using an X-ray diffraction device (Ultima IV manufactured by Rigaku). CuK α rays were used as the X-ray source, and the measurement conditions were as follows; tube voltage of 40 kV, tube current of 30 mA, scanning speed of 4°/min, and step of 0.02°. Based on the obtained X-ray diffraction profile, the integrated intensity of the background was obtained with 2θ in the range of 20.48° to 21.48°. In addition, the integrated intensity of the diffraction peak (2θ=21.98°) of cristobalite was obtained with 2θ in the range of 21.48° to 22.48°. The value obtained by dividing the integrated intensity of the diffraction peak by the integrated intensity of the background was 1.0. Based on the foregoing results, a clear diffraction peak deriving from the SiO₂ was not observed, and it was confirmed that the SiO₂ in the target is in an amorphous state.

In addition, a small piece cut out from the sintered compact was used to measure the oxygen amount with an oxygen analyzer and measure the nonmagnetic substance content with an ICP-AES analyzer. The measurement results were as follows; the oxygen amount in the target was 5.13 wt %, and the Si content was 4.46 wt %. When the SiO₂ content in the target was calculated with the atomic weight of Si as 28.0855 and the atomic weight of O as 15.9994, the result was 9.54 wt %. Accordingly, the content of O as the constituent of the SiO₂ was estimated as being 5.08 wt %. Subsequently, the residual oxygen amount of the target was obtained from the foregoing measurement results, and the result was 0.05 wt %.

Subsequently, the sintered compact was cut with a lathe into a shape having a diameter of 180.0 mm and a thickness of 5.0 mm in order to prepare a disk-shaped target. The obtained target was mounted on a magnetron sputtering device (C-3010 Sputtering System manufactured by Canon Anelva), and sputtered.

The sputtering conditions were as follows; input power of 1 kW and Ar gas pressure of 1.7 Pa, and, after pre-sputtering of 2 kWhr, deposition was performed on a silicon substrate having a 4-inch diameter for 20 seconds. Subsequently, the number of particles that adhered onto the substrate was measured using a particle counter. The number of particles in the foregoing case was 12 particles.

The foregoing results are summarized in Table 1. As shown in Table 1, with all Examples of the sputtering target of the present invention, the SiO₂ was amorphous and the residual oxygen amount of the target was 0.07 wt % or less. The number of particles that were generated during sputtering was 100 or less, and constantly fewer in comparison to the Comparative Examples.

TABLE 1

| | | | | Sintering | | | | |
|---|---|---|---|---|---|---|---|---|
| | | | | Temperature | | | | |
| | | | | (° C.) | | | Residual | |
| | | | SiO₂ Raw | | Hot | SiO₂ in | Oxygen | Number |
| | | | Material | Hot | Isostatic | Sintered | Concentration | of Particles |
| No. | Target Composition | Composition Ratio (Atomic Ratio) | Powder | Press | Pressing | Compact | (wt %) | (Particles) |
| Example 1 | Fe—Pt—SiO₂ | 84(50Fe—50Pt)—16SiO₂ | Amorphous | 1050 | 950 | Amorphous | 0.04 | 24 |
| Comparative | Fe—Pt—SiO₂ | 84(50Fe—50Pt)—16SiO₂ | Amorphous | 1050 | 950 | Cristobalite | 0.12 | 623 |
| Example 1 | | | | | | | | |
| Comparative | Fe—Pt—SiO₂ | 84(50Fe—50Pt)—16SiO₂ | Amorphous | 1150 | 950 | Cristobalite | 0.06 | 517 |
| Example 2 | | | | | | | | |
| Example 2 | Fe—Pt—Cu—SiO₂ | 80(45Fe—45Pt—10Cu)—20SiO₂ | Amorphous | 1000 | 950 | Amorphous | 0.05 | 17 |
| Comparative | Fe—Pt—Cu—SiO₂ | 80(45Fe—45Pt—10Cu)—20SiO₂ | Amorphous | 1000 | 950 | Cristobalite | 0.10 | 385 |
| Example 3 | | | | | | | | |
| Comparative | Fe—Pt—Cu—SiO₂ | 80(45Fe—45Pt—10Cu)—20SiO₂ | Amorphous | 1100 | 950 | Cristobalite | 0.05 | 553 |
| Example 4 | | | | | | | | |
| Example 3 | Fe—Pt—SiO₂—C | 80(50Fe—50Pt)—10SiO₂—10C | Amorphous | 1050 | 950 | Amorphous | 0.03 | 57 |
| Example 4 | Fe—Pt—SiO₂—BN | 82(50Fe—50Pt)—8SiO₂—10BN | Amorphous | 1050 | 950 | Amorphous | 0.05 | 35 |
| Comparative | Fe—Pt—SiO₂—BN | 82(50Fe—50Pt)—8SiO₂—10BN | Amorphous | 1050 | 950 | Cristobalite | 0.27 | 263 |
| Example 5 | | | | | | | | |
| Comparative | Fe—Pt—SiO₂—BN | 82(50Fe—50Pt)—8SiO₂—10BN | Amorphous | 1200 | 950 | Cristobalite | 0.04 | 744 |
| Example 6 | | | | | | | | |
| Example 5 | Fe—Pt—SiO₂—NbC | 86(55Fe—45Pt)—8SiO₂—6NbC | Amorphous | 1050 | 950 | Amorphous | 0.03 | 120 |
| Comparative | Fe—Pt—SiO₂—NbC | 86(55Fe—45Pt)—8SiO₂—6NbC | Amorphous | 1050 | 950 | Cristobalite | 0.12 | 567 |
| Example 7 | | | | | | | | |
| Example 6 | Fe—Pt—SiO₂—B₂O₃ | 88(50Fe—50Pt)—8SiO₂—4B₂O₃ | Amorphous | 950 | 950 | Amorphous | 0.01 | 23 |
| Example 7 | Fe—Pt—Ag—SiO₂ | 84(45Fe—45Pt—10Ag)—16SiO₂ | Amorphous | 950 | 950 | Amorphous | 0.05 | 12 |

### INDUSTRIAL APPLICABILITY

The present invention can provide a sintered compact sputtering target having a structure in which a nonmagnetic substance containing SiO₂ is dispersed in an Fe—Pt-based alloy and capable of suppressing the crystallization of SiO₂ into cristobalite, and reducing the amount of particles that is generated during sputtering. Since the generation of particles is low as described above, the present invention yields the effect of being able to considerably improve the production yield in the production process of magnetic thin films having a granular structure.

1. A sintered compact sputtering target configured from an alloy having a composition comprising Pt at a molecular ratio of 35 to 55% and remainder being Fe, and a nonmagnetic substance dispersed in the alloy, wherein the nonmagnetic substance contains at least SiO₂, SiO₂ is amorphous, and a residual oxygen amount, which is obtained by subtracting an amount of oxygen contained as a constituent of the nonmagnetic substance from a total amount of oxygen contained in the target, is 0.07 wt % or less.

2. The sputtering target according to claim 1, wherein the sputtering target includes, as an additive element to be added to the alloy, one or more types of elements selected from Ag, Au, B, Co, Cr, Cu, Ga, Ge, Mn, Mo, Nb, Ni, Pd, Re, Rh, Ru, Sn, Ta, W, V, and Zn at a molecular ratio of 0.5 to 15%.

3. The sputtering target according to claim 1 or claim 2, wherein the sputtering target includes, as a nonmagnetic substance other than SiO₂, one or more types selected from C (carbon), or a carbide of an element selected from B, Ca, Nb, Si, Ta, Ti, W, and Zr, or a nitride of an element selected from Al, B, Ca, Nb, Si, Ta, Ti, and Zr, or an oxide of an element selected from Al, B, Ba, Be, Ca, Ce, Cr, Dy, Er, Eu, Ga, Gd, Ho, Li, Mg, Mn, Nb, Nd, Pr, Sc, Sm, Sr, Ta, Tb, Ti, V, Y, Zn, and Zr.

4. The sputtering target according to claim 3, wherein a volume ratio of the nonmagnetic substance in the target is 10 to 55%.

5. The sputtering target according to claim 1, wherein the sputtering target includes, as a nonmagnetic substance other than SiO₂, one or more types selected from C (carbon), or a carbide of an element selected from B, Ca, Nb, Si, Ta, Ti, W, and Zr, or a nitride of an element selected from Al, B, Ca, Nb, Si, Ta, Ti, and Zr, or an oxide of an element selected from Al, B, Ba, Be, Ca, Ce, Cr, Dy, Er, Eu, Ga, Gd, Ho, Li, Mg, Mn, Nb, Nd, Pr, Sc, Sm, Sr, Ta, Tb, Ti, V, Y, Zn, and Zr.

6. The sputtering target according to claim 1, wherein a volume ratio of the nonmagnetic substance in the target is 10 to 55%.
